(19) United States
(12) Patent Application Publication
(10) Pub. No.: US 2014/0034484 A1
(43) Pub. Date: Feb. 6, 2014

(54) DEVICE FOR THE ELIMINATION OF LIQUID DROPLETS FROM A CATHODIC ARC PLASMA SOURCE

(71) Applicants: Andrew E. Fisk, Philadelphia, PA (US); Vasyliy I. Maslov, Kharkov (UA); Alexey A. Goncharov, Kiev (UA)

(72) Inventors: Andrew E. Fisk, Philadelphia, PA (US); Vasyliy I. Maslov, Kharkov (UA); Alexey A. Goncharov, Kiev (UA)

(21) Appl. No.: 13/563,282

(22) Filed: Jul. 31, 2012

(51) Int. Cl. C23C 14/24

(52) U.S. Cl. 204/192.38; 204/298.41

(57) ABSTRACT

A method and apparatus for depositing a metal onto a substrate using a cathodic arc plasma source as a source of metal ions. A plasma deposition apparatus has a vacuum chamber; and a conduit within the vacuum chamber having an input end and an output end. A substrate is within the vacuum chamber, positioned to receive a plasma at the output end of the conduit. A cathodic arc plasma source within the vacuum chamber is positioned to inject a composition comprising a mixture of a plasma and electrons into the input end of the conduit toward the output end of the conduit. A magnetic field generator establishes a magnetic field within the conduit a plurality of electrodes located within the magnetic field and an electric field generator establishes an electric field within the conduit. The apparatus reduces or eliminates liquid metal droplets emitted from such a plasma source.

### BACKGROUND OF THE INVENTION

1. Field of the Invention

The invention relates to a method and apparatus for depositing a material, such as a metal onto a substrate using a cathodic arc plasma source as a source of ions or a similar device. More particularly, the invention relates to an apparatus which reduces or eliminates unwanted liquid metal droplets which are typically emitted from such a cathodic arc plasma source.

2. Description of the Related Art

There is great commercial interest in coating the surface of a substrate with a material such as a metal having a high density, uniform microstructure and fine grain size. Such substrates find use in the production of hard disk drives, architectural glass, protective coatings, decorative coatings, wear resistant coatings, and to synthesize an extremely hard film to protect the surface of cutting tools. Such coatings are known to be produced by vacuum coating techniques, particularly by physical vapor deposition. It is desirable to produce these coatings as quickly as possible at the lowest possible cost. Many types of physical vapor deposition coating techniques are known, including magnetron sputtering, electron beam physical vapor deposition, and pulsed laser deposition. Deposition with a magnetron plasma source is often used when a highly dense, uniform microstructure is required, however, this method sacrifices deposition rate for a high coating quality. Electron beam physical vapor deposition is often employed for high deposition rate applications but requires expensive electron beam equipment. Another disadvantage is the low ion energy of electron beam physical vapor deposition which makes densification of the film difficult.

Another coating method is cathodic arc deposition. This technique evaporates the metal coating material at a very high rate using a meandering arc and has deposition rate close to that of electron beam physical vapor deposition, but with less complex equipment, which is similar to magnetron plasma sputtering.

However, cathodic arc deposition suffers from a very serious disadvantage, namely liquid droplets of coating material released from the cathodic arc source form and attach to the coating equipment. With the high vaporization rate of metal coating materials, small droplets of liquid metal are often released as a result of the arc dwelling in once spot. Efforts have been made to minimize these droplets such as by rapidly scanning the arc across the surface of the target substrate, and applying a pulsed current to the arc to reduce hot spots. While these developments have been successful in reducing the size and quantity of droplets, it is still inadequate and secondary filtering must be employed in order to achieve fine grained microstructures with high density. Secondary filtering of the plasma can remove almost all droplets and microdroplets from the vapor flow and result in a dense, fine grained material with excellent properties. These methods include conventional filters such as metal screens placed in the vapor flow allowing only fine particles to pass, and more sophisticated methods such as S-shaped magnetic guides which separate heavier particles based on inertia.

Unfortunately the methods currently available for filtering the droplets from the plasma result in a 50%-70% reduction in deposition rate because they rely on the physical removal of mass from the vapor flow. This decrease in deposition rate counteracts the high vaporization rate of the cathodic arc technique and therefore magnetron plasma sputtering is often chosen over cathodic arc due to the simplicity of design and nearly equivalent deposition rate. Cathodic arc is a physical vapor deposition technique in which an electric arc is used to vaporize material from a cathode. The vaporized material then condenses on a target substrate, forming a thin film. The technique can be used to deposit metallic, ceramic, and composite films. U.S. Pat. No. 6,548,817 discloses a filter made of magnetic coils. The droplets are filtered by their inertia as the vapor flow passes through the coils and the magnetic field confines and steers the plasma/vapor flow. The device achieves filtering by removing mass from the vapor stream. However, this and other similar techniques remove a minimum of 50% of the plasma flux, resulting in very low efficiencies. U.S. Pat. Nos. 7,300,559; 7,252,745 and 6,663,755 teach a filtered cathodic arc deposition apparatus, however, these devices filter out the microparticles rather than evaporating them and incorporating them into the plasma. It would therefore be advantageous to provide an apparatus and a method for reducing or eliminating the liquid droplets from the vapor flow without reducing the mass of the material from the vapor flow. The present invention provides such an apparatus and technique while retaining approximately 85% or more of the deposition rate. The invention provides a plasma deposition apparatus having a high ion density and a high number of fast electrons, which coats a substrate located in a confined body. By simultaneously applying both magnetic and electric field located between a cathodic arc plasma source and a target substrate, a plasma stream of a metal or other material is applied onto the target substrate to be coated in a manner such that the plasma is free from obstruction so that it avoids contacting surfaces of the apparatus. The plasma deposition apparatus is considered to be a plasma lens and is a part of an apparatus providing a magnetic field, an electric field, a cathode and an anode. The cathode and anode are separated by a high potential. As the plasma enters the field combination, the droplets of liquid metal are acted on by fast electrons and vaporized. This newly formed vapor is consequently acted on by the ions in the plasma and the previously un-ionized molten metal droplet becomes incorporated into the highly ionized vapor flow. Due to the nature of the plasma lens, the vapor is focused and contained in center axis of the apparatus, and therefore the vapor avoids coating the walls of the apparatus. The molten droplets are vaporized and essentially eliminated without loss of mass to the vapor flux as with other deposition methods.

### SUMMARY OF THE INVENTION

The invention provides a plasma deposition apparatus comprising a vacuum chamber; a conduit within the vacuum chamber, said conduit having an input end and an output end; a substrate within the vacuum chamber, positioned to receive a plasma at the output end of the conduit; a cathodic arc plasma source within the vacuum chamber, positioned to inject a composition comprising a mixture of a plasma and electrons into the input end of the conduit toward the output end of the conduit; a magnetic field generator for establishing a magnetic field within the conduit; a plurality of electrodes located within the magnetic field and an electric field generator for establishing an electric field within the conduit.

The invention also provides a method for reducing the quantity of liquid droplets from a plasma which comprises:

a) providing a plasma deposition apparatus comprising a vacuum chamber; a conduit within the vacuum chamber, said conduit having an input end and an output end; a substrate within the vacuum chamber, positioned to receive a plasma at the output end of the conduit; a cathodic arc plasma source within the vacuum chamber, positioned to inject a composition comprising a mixture of a plasma and electrons into the input end of the conduit toward the output end of the conduit; a magnetic field generator for establishing a magnetic field within the conduit; a plurality of electrodes located within the magnetic field and an electric field generator for establishing an electric field within the conduit;

b) injecting a composition comprising a mixture of a plasma and electrons from the cathodic arc plasma source into the input end of the conduit toward the output end of the conduit;

c) simultaneously establishing a magnetic field within the conduit with the magnetic field generator, and establishing an electric field within the conduit with the electric field generator.

### BRIEF DESCRIPTION OF THE DRAWINGS

FIG. 1 illustrates a schematic view of the plasma deposition apparatus according to the invention.

FIG. 2 shows a scanning electron micrograph of the resulting specimen target when the apparatus is operated with a magnetic field of 0 Gauss, an electric field of 0 volts.

FIG. 3 shows a scanning electron micrograph of the resulting specimen target when the apparatus is operated without crossed electric/magnetic fields.

FIG. 4 is a scanning electron micrograph of the resulting specimen target when the apparatus is operated with crossed electric/magnetic fields according to the invention.

FIG. 5 is a chart showing the microdroplet radius distribution on the specimen targets under the conditions of the Example.

### DESCRIPTION OF THE INVENTION

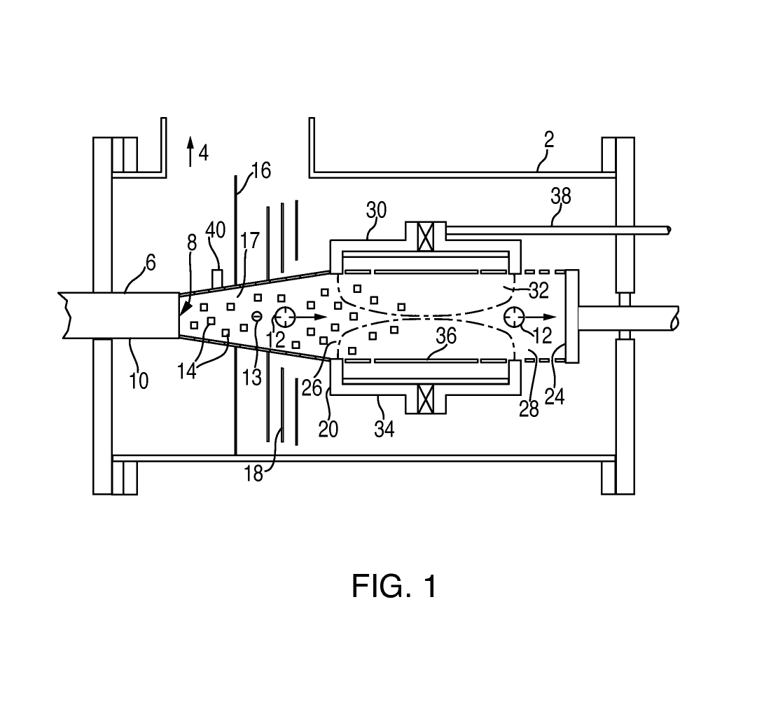

FIG. 1 is a schematic view of the plasma deposition apparatus according to the invention. The apparatus comprises a vacuum chamber 2. All air and other gases are removed from the vacuum chamber via a pump 4, not shown. Vacuum chambers are well known in the art. The vacuum chamber may be composed of any suitable metal or ceramic material, however, stainless steel is preferred since it avoids corrosion. Within the vacuum chamber 2 is a cathodic arc plasma source 6, which is generally commercially available from Arcomac. The cathodic arc evaporation process begins when a trigger 8 initiates the striking of a high current, low voltage arc on the surface of a cathode 10 that gives rise to a small, highly energetic emitting area which results in a high velocity jet of vaporized cathode material. Cathodic materials to be vaporized and deposited non-exclusively include metals such as copper and tantalum, carbon, diamond-like carbon, ceramics, and combinations thereof. The arc has an extremely high power density resulting in a high level of ionization and comprises a plasma 12 containing multiple charged ions, electrons 13, neutral particles, and clusters of atoms or molecules in the form of microdroplets 14 of vaporized cathode material. Since the plasma beam from the cathodic arc source contains large clusters of atoms or molecules, it cannot be used for some applications without filtering. There are many proposed designs for microparticle filters known in the art, however, these have been only partially satisfactory. The anode for the system can be either the vacuum chamber wall or a discrete anode 16 which assists in directing the jet of vaporized cathode material. Discrete anode 16 has an aperture 17 through which the plasma 12 and microdroplets 14 flow. Optionally, but preferably, the jet then passes through one or more screens 18 between the cathodic arc plasma source 6 a conduit 20 within the vacuum chamber. The aperture 17 and screens 18 assist in directing the composition comprising a mixture of plasma and electrons from the cathodic arc plasma source 6 into a conduit 20, which is usually a hollow cylinder, but may be some other shapes. The purpose of the conduit 20 is to direct the plasma containing stream to the surface of a substrate 24 to be coated. The conduit 20 has an input end 26 and an output end 28. The substrate 24, or specimen target, is also within the vacuum chamber 2, and is positioned to receive the plasma at the output end 28 of the conduit 20. Useful substrates non-exclusively include metals such as stainless steel, glass, semiconductors, polymers, ceramics and combinations thereof.

Positioned near the conduit 20, and preferably within vacuum chamber 2 at the outside of conduit 20 is a magnetic field generator 30 for establishing a magnetic field 32 within the conduit. The magnetic field generator 30 is a magnetic coil and reference numeral 32 represents the magnetic field lines. The magnetic field generator is usually capable of generating a magnetic field of from about 200 Gauss to about 1,000 Gauss, preferably from about 300 Gauss to about 700 Gauss, and more preferably from about 300 Gauss to about 600 Gauss. Also positioned near the conduit 20, and preferably within vacuum chamber 2 at the outside of conduit 20 is an electric field generator 34 for establishing an electric field within the conduit. Reference numeral 36 represents an electrode positioned within the conduit, for which the strong radial electrical field is supported. The electric field generator is usually capable of generating an electric field of from about 5×10⁵ Vm⁻¹ to about 30×10⁶ Vm⁻¹, preferably from about 9×10⁵ Vm⁻¹ to about 30×10⁶ Vm⁻¹, and more preferably from about 10×10⁶ Vm⁻¹ to about 25×10⁶ Vm⁻¹. It has been found that the application of the combined magnetic and electric field substantially reduces or eliminates the presence of microdroplets within the composition comprising a mixture of a plasma and electrons initially emitted from the cathodic arc plasma source. In another embodiment, the plasma deposition apparatus additionally has a cooling apparatus 38 within the vacuum chamber 2 for reducing the temperature within the vacuum chamber 2. In yet another embodiment, the composition comprising a mixture of a plasma and electrons further comprises an inert gas. Thus the inventive apparatus may further comprise an inert gas injector 40 for injecting a stream of an inert gas into the composition comprising a mixture of plasma and electrons. Inert gases non-exclusively include helium, nitrogen, argon, xenon, and krypton.

Thus the invention provides a method for reducing the quantity of liquid microdroplets from a plasma by providing the above described plasma deposition apparatus, injecting a composition comprising a mixture of a plasma and electrons from the cathodic arc plasma source into the input end of the conduit toward the output end of the conduit; and simultaneously establishing a magnetic field within the conduit with the magnetic field generator, and establishing an electric field within the conduit with the electric field generator.

In use, a flow of a composition comprising a mixture of a plasma 12 and electrons flows from a cathodic arc plasma source 6 into the input end 26 of conduit 20 toward the output end 28 of the conduit 20. The flow passes through aperture 17 and screens 18. The flow from the cathodic arc plasma source comprises a mixture of a plasma 12, electrons 13 and droplets 14, extends from the cathode 10. The mixture then travels through the aperture 17, optional screens 18, and into the conduit 20 as shown in FIG. 1. The conduit 20 has a length L and diameter D, on which a voltage U is supplied. The voltage U forms a large, intense electrical field layer of thickness A. This field is focused radially inside the conduit and penetrates into the center of the plasma flow. The conduit 20 is also in a magnetic field 32 created by magnets 30 located radially along the outer diameter of the conduit 20. The value of this magnetic field following the formula:

ρ_{He}<<D<<ρ_{Hi}.

The values for ρ_{He} and ρ_{Hi} are the electron and ion Larmour radiuses respectively. In this case, electrons within the magnetic field are magnetized but ions are not. The electron mobility in the cross magnetic field is strongly suppressed, and along the magnetic field there is free electron mobility. Under these conditions the electrons are confined to follow the magnetic field lines and acquire the potential U of the applied electric field. The electrical fields are crossed in relation to the magnetic fields and under these conditions an equipotential electric field is set along the magnetic field lines. As the electrons of the plasma flow enter the magnetic field they are magnetized and held within the axial magnetic lines. This causes the non-magnetized ions of the plasma flow to be focused toward the center axis of the conduit 20. An increase in the magnetic field would therefore increase the focusing effect of the ions in the plasma. This leads to the effect of preventing ion bombardment and therefore deposition onto the conduit walls. If the magnetic field is increased beyond an optimal value, the extension of the electrons toward the center axis of the conduit 20 interferes with the flow of ions and can limit the throughput of the device. In this case the optimum magnetic field for effective damping of the flow while allowing for plasma passage is estimated and it is found that the most effective control of the plasma flow is achieved at a rather small magnetic field ω_{He}<<ωₚₑ wherein ωₚₑ is the plasma electron frequency. While the containment of ions axially near the center of the conduit 20 and the addition of an optional glow discharge along the outer radius of the conduit 20 may have some effect on microdroplets the larger contribution comes from the creation of an electron beam within the device. As a result of the electron emission and crossed electrical/magnetic field, an electron beam with velocity V_{b} and current density (j_{b}γjᵢ, γ is the second ion-electron emission coefficient) is formed along the axis of the device near the outer radius of the device in a thin layer Δ<<V_{b}/ω_{He} (ω_{He} is the electron cyclotron frequency). This beam provides evaporation of the droplets as well as ionization. This electron beam is an additional source of energy to the system. During movement of droplets through the apparatus, the additional energy added by the electron beam Δε_{b} into the plasma is larger than the all energy of the ion flow Δε_{b}>>Δεᵢ. Under the influence of the electron beam, the plasma flow microdroplets acquire the floating potential that follows the equation:

jᵢ=jₑ,

jₑ=n₀Vₜₕₑ exp(−eφ_{d}/Tₑ), jᵢ=n₀(2εᵢ/mᵢ)^{1/2}

This determines the negative charge on the droplet. φ_{d} is the electrostatic potential of the droplet, jᵢ is the current density of ions on the dropplet, εᵢ is the ion energy, Vₜₕₑ is the electron thermal velocity. During the microdroplet movement through apparatus, the electron beam significantly increases the energy of the plasma. This additional energy supplied by the electrons is effective in evaporation of droplets. As the droplet increase in electrostatic potential φ_{d}≈Tₑ/e, evaporation takes place.

The following non-limiting example serves to illustrate the invention.

### EXAMPLE

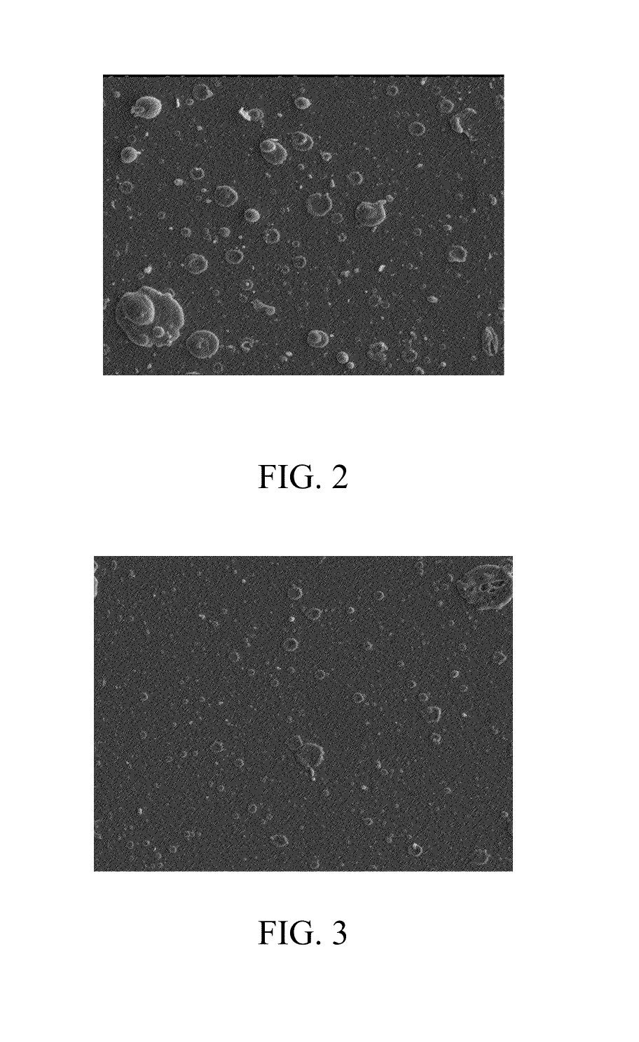

The apparatus of FIG. 1 is constructed. The cathodic arc plasma source is an standard industry, commercially available apparatus. The magnetic field is created by permanent magnets which provide a magnetic field of about 360 Gauss at the axis of the conduit. An electric field is applied such that the voltage at the axis of the conduit ranges from about −1 kV to about −1.5 kV. The anode aperture is about 70 mm wide and the length of the conduit is about 15 cm. Using the cathodic arc plasma source, copper was evaporated onto stainless steel specimen targets, which were then viewed by an electron microscope. FIGS. 2-4 show the result for different operating conditions.

FIG. 2 is a scanning electron micrograph of the resulting specimen target when the apparatus is operated with a magnetic field of 0 Gauss, an electric field of 0 volts. The plasma ion current at the substrate was 4 mA.

FIG. 3 is a scanning electron micrograph of the resulting specimen target when the apparatus is operated without crossed electric/magnetic fields. The magnetic field was 0 Gauss, and the electric field was −1 kV. The plasma ion current at the substrate was 5 mA.

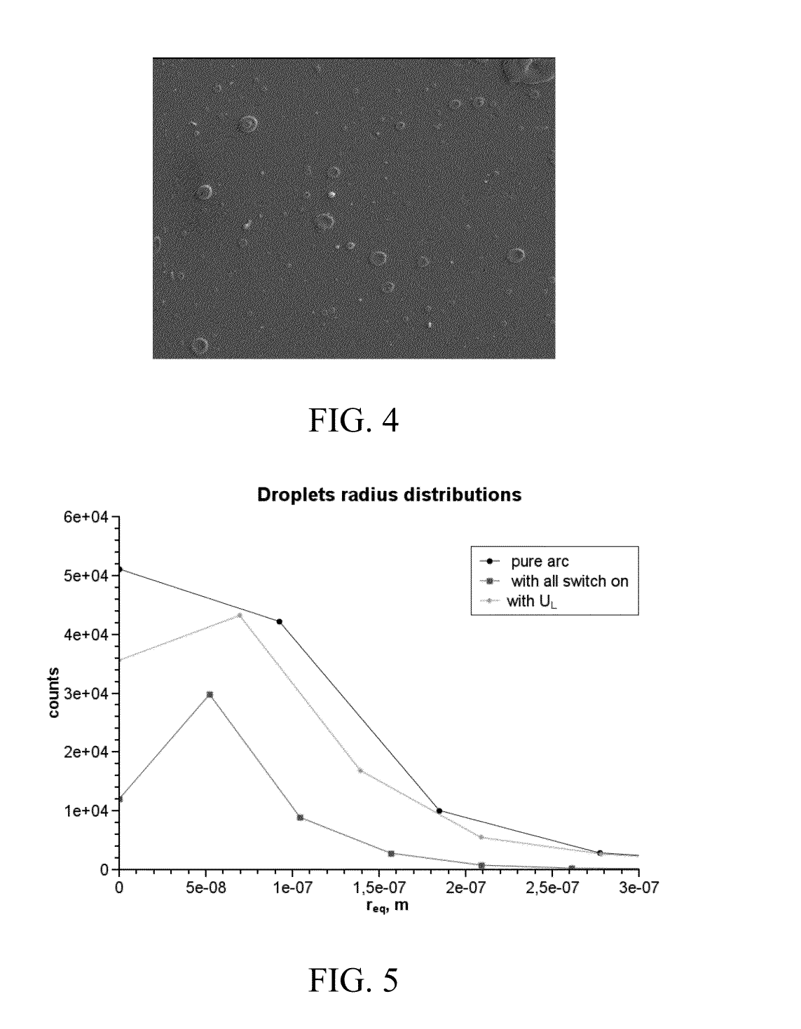

FIG. 4 is a scanning electron micrograph of the resulting specimen target when the apparatus is operated with crossed electric/magnetic fields according to the invention. The magnetic field was 360 Gauss, and the electric field was −1 kV. The plasma ion current was 30 mA.

FIG. 5 is a chart showing the count of the number of microdroplets vs. the microdroplet radius distribution r_{eq} in meters, on the specimen targets under the conditions of the Example. The uppermost line in the chart of FIG. 5 shows the microdroplet count without the magnetic and electric fields applied. The center line shows the microdroplet count with only high voltage applied. In this case, a glow discharge and hollow cathode effect are present to create electrons near the outer radius of the conduit but there is no crossed electrical/magnetic field. Therefore for this condition there is no additional energy supplied to the system by the electron beam. The lowest line microdroplet count with both the magnetic and electric fields applied. The SEM's and the chart demonstrate the dramatic reduction in the number and diameter of microdroplets formed using the apparatus of the invention.

While the present invention has been particularly shown and described with reference to preferred embodiments, it will be readily appreciated by those of ordinary skill in the art that various changes and modifications may be made without departing from the spirit and scope of the invention. It is intended that the claims be interpreted to cover the disclosed embodiment, those alternatives which have been discussed above and all equivalents thereto.

What is claimed is:

1. A plasma deposition apparatus comprising a vacuum chamber; a conduit within the vacuum chamber, said conduit having an input end and an output end; a substrate within the vacuum chamber, positioned to receive a plasma at the output end of the conduit; a cathodic arc plasma source within the vacuum chamber, positioned to inject a composition comprising a mixture of a plasma and electrons into the input end of the conduit toward the output end of the conduit; a magnetic field generator for establishing a magnetic field within the conduit; a plurality of electrodes located within the magnetic field and an electric field generator for establishing an electric field within the conduit.

2. The plasma deposition apparatus of claim 1 wherein the magnetic field generator is positioned within the vacuum chamber adjacent to the conduit.

3. The plasma deposition apparatus of claim 1 wherein the magnetic field generator is capable of generating a magnetic field of from about 200 Gauss to about 1,000 Gauss.

4. The plasma deposition apparatus of claim 1 wherein the electric field generator is positioned within the vacuum chamber adjacent to the conduit.

5. The plasma deposition apparatus of claim 1 wherein the electric field generator is capable of generating an electric field of from about 5×10⁵ Vm⁻¹ to about 30×10⁶ Vm⁻¹.

6. The plasma deposition apparatus of claim 1 further comprising a cooling apparatus within the vacuum chamber for reducing the temperature within the vacuum chamber.

7. The plasma deposition apparatus of claim 1 further comprising one or more screens between the cathodic arc plasma source and the input end of the conduit for directing the composition comprising a mixture of plasma and electrons from the cathodic arc plasma source into the input end of the conduit.

8. The plasma deposition apparatus of claim 1 wherein the composition comprising a mixture of plasma and electrons further comprises an inert gas.

9. The plasma deposition apparatus of claim 1 further comprising an inert gas injector for injecting a stream of an inert gas into the composition comprising a mixture of plasma and electrons.

10. A method for reducing the quantity of liquid droplets from a plasma which comprises:
a) providing a plasma deposition apparatus comprising a vacuum chamber; a conduit within the vacuum chamber, said conduit having an input end and an output end; a substrate within the vacuum chamber, positioned to receive a plasma at the output end of the conduit; a cathodic arc plasma source within the vacuum chamber, positioned to inject a composition comprising a mixture of a plasma and electrons into the input end of the conduit toward the output end of the conduit; a magnetic field generator for establishing a magnetic field within the conduit; a plurality of electrodes located within the magnetic field and an electric field generator for establishing an electric field within the conduit;
b) injecting a composition comprising a mixture of a plasma and electrons from the cathodic arc plasma source into the input end of the conduit toward the output end of the conduit;
c) simultaneously establishing a magnetic field within the conduit with the magnetic field generator, and establishing an electric field within the conduit with the electric field generator.

11. The method of claim 10 wherein the magnetic field generator is positioned within the vacuum chamber adjacent to the conduit.

12. The method of claim 10 wherein the magnetic field generator generates a magnetic field of from about 200 Gauss to about 1,000 Gauss.

13. The method of claim 10 wherein the electric field generator is positioned within the vacuum chamber adjacent to the conduit.

14. The method of claim 10 wherein the electric field generator generates an electric field of from about 5×10⁵ Vm⁻¹ to about 30×10⁶ Vm⁻¹.

15. The method of claim 10 wherein a temperature within the vacuum chamber is reduced by a cooling apparatus within the vacuum chamber.

16. The method of claim 10 wherein the composition comprising a mixture of plasma and electrons is directed from the cathodic arc plasma source into the input end of the conduit by one or more screens between the cathodic arc plasma source and the input end of the conduit.

17. The method of claim 10 wherein the composition comprising a mixture of plasma and electrons further comprises an inert gas.

18. The method of claim 10 further comprising an inert gas injector for injecting a stream of an inert gas into the composition comprising a mixture of plasma and electrons.

19. The method of claim 10 wherein the composition comprising a mixture of plasma and electrons, comprises a metal, carbon, diamond-like carbon, ceramics, and combinations thereof.

20. The method of claim 10 wherein the substrate comprises a metal, glass, a semiconductor, a polymer, a ceramic, and combinations thereof.
